(19) United States
(12) Patent Application Publication
(10) Pub. No.: US 2025/0307482 A1
(43) Pub. Date: Oct. 2, 2025

(54) GENERATIVE FILLING OF DESIGN CONTENT

(71) Applicant: FIGMA, INC., San Francisco, CA (US)

(72) Inventors: Shirley MIAO, San Francisco, CA (US); Oscar WONG, San Francisco, CA (US); Yi Tang Jackie CHUI, San Francisco, CA (US); Karl JIANG, San Francisco, CA (US); Kari BANCROFT, San Francisco, CA (US); Cemre GUNGOR, San Francisco, CA (US)

(21) Appl. No.: 19/090,267

(22) Filed: Mar. 25, 2025

Related U.S. Application Data
(60) Provisional application No. 63/570,152, filed on Mar. 26, 2024.

(51) Int. Cl. G06F 30/12

(52) U.S. Cl. CPC G06F 30/12

(57) ABSTRACT

A network computer system provides interactive graphic design system instructions for performing generative filling of design content. The network computer system determines a set of repeating design elements within a design interface. The network computer system also determines input into a machine learning model that includes (i) example content associated with the set of repeating design elements and (ii) one or more instructions associated with the example content. The network computer system populates at least a portion of the set of repeating design elements with additional content generated by the machine learning model in response to the input.

### CROSS-REFERENCE TO RELATED APPLICATIONS

This application claims priority benefit of United States Provisional Patent Application titled “GENERATIVE FILLING OF DESIGN CONTENT,” Ser. No. 63/570,152, filed Mar. 26, 2024. The subject matter of this related application is hereby incorporated herein by reference

### TECHNICAL FIELD

Examples described herein relate to a network computer system, and more specifically, to generative filling of design content in interactive graphic design systems.

### BACKGROUND

Software design tools have many forms and applications. In the realm of application user interfaces, for example, software design tools require designers to blend functional aspects of a program with aesthetics and even legal requirements, resulting in a collection of pages which form the user interface of an application. For a given application, designers often have many objectives and requirements that are difficult to track.

### BRIEF DESCRIPTION OF THE DRAWINGS

FIG. 1 illustrates an interactive graphic design system in accordance with one or more embodiments.

FIG. 2A illustrates an example rendering of a design interface that includes a set of repeating design elements in accordance with one or more embodiments.

FIG. 2B illustrates an example rendering of a design interface that includes a set of repeating design elements in accordance with one or more embodiments.

FIG. 2C illustrates an example rendering of a design interface that includes a set of repeating design elements in accordance with one or more embodiments.

FIG. 2D illustrates an example rendering of a design interface that includes a set of repeating design elements in accordance with one or more embodiments.

FIG. 3A illustrates an example rendering of a design interface and a set of hierarchical structures representing a set of repeating design elements within the design interface in accordance with one or more embodiments.

FIG. 3B illustrates a set of fill data associated with a set of repeating design elements in accordance with one or more embodiments.

FIG. 4 illustrates a process for performing generating filling of design content in accordance with one or more embodiments.

FIG. 5 illustrates a computer system on which one or more embodiments can be implemented.

FIG. 6 illustrates a user computing device for use with one or more examples, as described.

### DETAILED DESCRIPTION

Examples include a computer system that can operate to implement an interactive graphic design system that enables users to create, update, and/or customize components in a design interface. The design interface can include design elements that are rendered by the integrated graphic design system on a canvas. In examples, a computer system is configured to implement an interactive graphic design system for designers, such as user interface designers (“UI designers”), web designers, and web developers. Among other advantages, examples as described enable such users to leverage generative machine learning techniques to “fill in” content in reusable components within the design interface.

In some examples, a design interface is represented as a set of interconnected nodes arranged in a graph and/or another hierarchical structure. Workspace data for a design interface may include data describing the set of nodes along with data describing the hierarchical structure. Within the hierarchical structure, relationships between nodes may denote an arrangement of layers, where individual layers correspond to a frame object, a group of frame objects, or a specific type of frame object. In context of such examples, nodes in the layers can represent design elements within the design interface. Each node and/or layer can also be characterized by a set of attributes that reflect the visual appearance of the corresponding design element. The attributes of each node and/or layer can be selected or manipulated by users. By way of illustration, a user can modify individual nodes and/or layers by specifying (i) a numeric value to represent a line, corner or dimensional characteristic of a frame object; (ii) a color value (e.g., which can be formatted as HEX, HSB, HSL, CSS and RGB) for a background, or for a fill, line or shading attribute of an object; (iii) a shape characteristic; and/or (iv) a text string attribute.

In some embodiments, a main component defines properties of one or more design elements. Instances of the main component may correspond to copies of the main component that can be reused in design interfaces. These instances are linked to the main component and receive updates made to the main component, thereby allowing designers to show design elements with different content while adhering to a consistent design.

In one or more embodiments, a large language model (LLM), generative model, and/or another type of machine learning model is used to “fill in” content associated with a component and/or another portion of a design interface that includes repeating design elements. The repeating design elements may be arranged within a list, table, grid, and/or another layout. The repeating design elements may be identified as having a similar representation and/or arrangement of layers and/or nodes in the hierarchical structure. Upon detecting the repeating design elements in a portion of the design interface (e.g., in response to a user selection of the portion and/or other input), content associated with one or more of the repeating design elements and/or one or more instructions are provided as input to the machine learning model. The instructions may include directives and/or customizations related to generating and/or formatting additional content that can be used in the repeating design elements. After the machine learning model produces the additional content, the additional content is incorporated into the repeating design elements within the portion of the design interface.

Examples may be deployed in a collaborative environment that allows multiple users to concurrently update a design interface, and may streamline the retrieval and management of large design systems and improve the efficient functioning of computers by leveraging, directing, and integrating the capabilities of a large language model (LLM), generative model, and/or another type of machine learning model into the generation, update, and/or customization of design elements within design interfaces. For example, a conventional design tool may require a designer to manually generate and/or customize content in individual fields and/or design elements within a series of repeating design elements. This process can thus be tedious, time-consuming, and resource-intensive (e.g., as the design tool is executed to process input from the user and make corresponding changes to the repeating design elements).

In contrast, the disclosed interactive graphic design system automatically detects repeating design elements within a portion of a design interface, provides content in one or more of the design elements to a generative model, and populates the content in some or all of the repeating design elements with similar content outputted by the generative model. As a result, the user can efficiently create design interfaces that include repeating design elements without incurring significant time and resource overhead in manually editing the content within the repeating design elements. The interactive graphic design system can additionally adjust the content in the repeating design elements based on existing content in one or more of the design elements, instructions from the user, and/or other types of input. Thus, by streamlining and automating the process of generating content in repeating design elements, the interactive graphic design system provides a technological improvement and an improvement in computer technology over existing manual techniques for generating and updating design elements.

One or more embodiments described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more embodiments described herein can be implemented using programmatic modules, engines, or components. A programmatic module, engine, or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs, and/or machines.

Some embodiments described herein can generally require the use of computing devices, including processing and memory resources. For example, one or more embodiments described herein may be implemented, in whole or in part, on computing devices such as servers, desktop computers, cellular or smartphones, tablets, wearable electronic devices, laptop computers, printers, digital picture frames, network equipment (e.g., routers) and tablet devices. Memory, processing, and network resources may all be used in connection with the establishment, use, or performance of any embodiment described herein (including with the performance of any method or with the implementation of any system).

Furthermore, one or more embodiments described herein may be implemented through the use of instructions that are executable by one or more processors. These instructions may be carried on a computer-readable medium. Machines shown or described with figures below provide examples of processing resources and computer-readable mediums on which instructions for implementing embodiments of the invention can be carried and/or executed. In particular, the numerous machines shown with embodiments of the invention include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash memory (such as carried on smartphones, multifunctional devices, and/or tablets), and magnetic memory. Computers, terminals, network enabled devices (e.g., mobile devices, such as cell phones) are all examples of machines and devices that utilize processors, memory, and instructions stored on computer-readable mediums. Additionally, embodiments may be implemented in the form of computer-programs, or a computer usable carrier medium capable of carrying such a program. SYSTEM DESCRIPTION

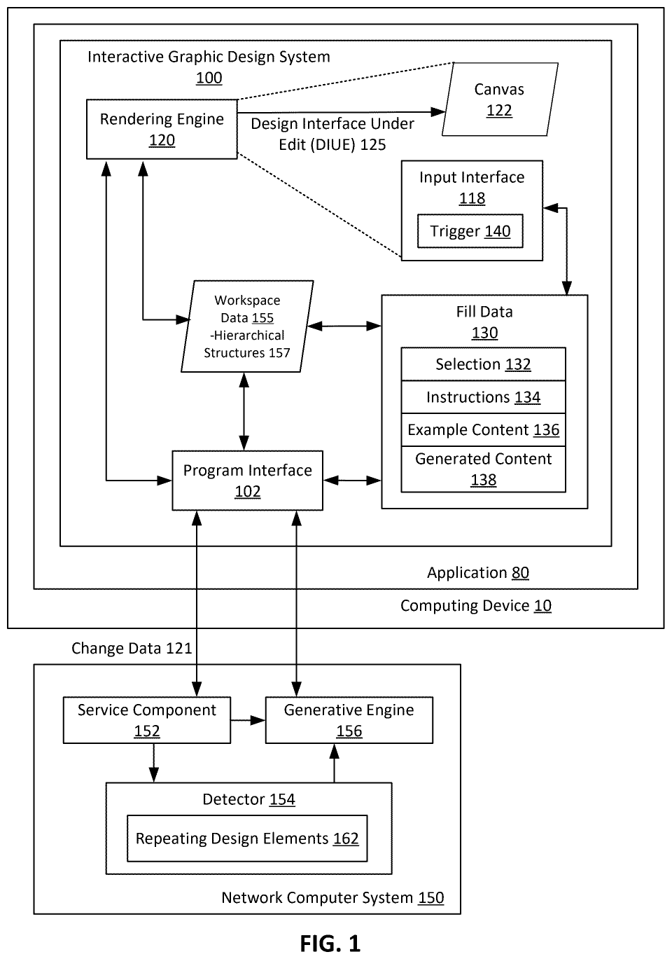

FIG. 1 illustrates an interactive graphic design system (IGDS) 100, according to one or more examples. The IGDS 100 can be implemented in any one of multiple different computing environments, including as a device-side application, as a network service, and/or as a collaborative platform. In examples, the IGDS 100 can be implemented using a web-based application 80 that executes on a web browser of a user computing device 10. In other examples, the IGDS 100 can be implemented through use of a dedicated web-based application. As an addition or alternative, one or more components of the IGDS 100 can be implemented as distributed system, such that processes described with various examples execute on both a network computer (e.g., server) and on the computing device 10.

According to examples, the IGDS 100 can be implemented on a user computing device 10 to enable a corresponding user to create, view, and/or modify various types of design interfaces using graphical elements. A design interface may include any layout of content and/or interactive elements, such as (but not limited to) a web page. The IGDS 100 can include processes that execute as or through a browser application 80 that is installed on the computing device 10.

In examples, the application 80 can correspond to a commercially available browser, such as GOOGLE CHROME (developed by GOOGLE, INC.), SAFARI (developed by APPLE, INC.), and INTERNET EXPLORER (developed by the MICROSOFT CORPORATION). In such examples, the processes of the IGDS 100 can be implemented as scripts and/or other embedded code which web-based application 80 downloads from a network site. For example, the web-based application 80 can execute code that is embedded within a webpage to implement processes of the IGDS 100. The application 80 can also execute the scripts to retrieve other scripts and programmatic resources (e.g., libraries) from the network site and/or other local or remote locations. By way of example, the application 80 may execute JAVASCRIPT embedded in an HTML resource (e.g., webpage structured in accordance with HTML 5.0 or other versions, as provided under standards published by W3C or WHATWG consortiums). In other variations, the IGDS 80 can be implemented through use of a dedicated application, such as a web-based application.

In some examples, application 80 retrieves programmatic resources for implementing the IGDS 100 from a network site. As an addition or alternative, application 80 can retrieve some or all of the programmatic resources from a local source (e.g., local memory residing with the computing device 10). Application 80 may also access various types of data sets in providing functionality such as described with the IGDS 100. The data sets can correspond to files and libraries, which can be stored remotely (e.g., on a server, in association with an account) or locally.

The IGDS 100 can be implemented as web code that executes in the application 80. This web code can include (but is not limited to) HyperText Markup Language (HTML), JAVASCRIPT, Cascading Style Sheets (CSS), other scripts, and/or other embedded code which the browser application 80 downloads from a network site. For example, the application 80 can execute web code that is embedded within a web page, causing the IGDS 100 to execute at the user computer device 10 in the browser application 80. The web code can also cause the application 80 to execute and/or retrieve other scripts and programmatic resources (e.g., libraries) from the network site and/or other local or remote locations. By way of example, the application 80 may include JAVASCRIPT embedded in an HTML resource (e.g., web page structured in accordance with HTML 5.0 or other versions, as provided under standards published by W3C or WHATWG consortiums) that is executed by the browser application 80. In some examples, the rendering engine 120 and/or other components may utilize graphics processing unit (GPU) accelerated logic, such as provided through WebGL (Web Graphics Library) programs which execute Graphics Library Shader Language (GLSL) programs that execute on GPUs.

In examples, the IGDS 100 includes processes that execute through a web-based application 80 that is installed on the computing device 10. The web-based application 80 can execute scripts, code and/or other logic to implement functionality of the IGDS 100. Additionally, in some variations, the IGDS 100 can be implemented as part of a network service, where the application 80 communicates with one or more remote computers (e.g., server used for a network service) to executes processes of the IGDS 100.

In examples, the application 80 loads processes and data for providing the IGDS 100 on the computing device 10. The IGDS 100 can include a rendering engine 120 that enables users to create, edit and update graphic design files.

According to examples, a user of device 10 operates the application 80 to access a network site, where programmatic resources are retrieved and executed to implement the IGDS 100. In this way, the user may initiate a session to implement the IGDS 100 to create, view, and/or modify a design interface. In some embodiments, the IGDS 100 includes a program interface 102, an input interface 118, and a rendering engine 120. The program interface 102 can include one or more processes that execute to access and retrieve programmatic resources from local and/or remote sources.

The IGDS 100 can include processes represented by program interface 102, rendering engine 120, and input interface 118. Depending on implementation, the components can execute on the computing device 10, on a network system (e.g., server or combination of servers), or on the user device 10 and a network system (e.g., as a distributed process).

In some implementations, the program interface 102 can generate a canvas 122 using programmatic resources that are associated with the browser application 80 (e.g., an HTML 5.0 canvas). As an addition or variation, the program interface 102 can trigger or otherwise cause the canvas 122 to be generated using programmatic resources and data sets (e.g., canvas parameters) which are retrieved from local (e.g., memory) or remote sources (e.g., from network service).

The program interface 102 includes processes to receive and send data for implementing components of the IGDS 100. Additionally, the program interface 102 can be used to retrieve, from local or remote sources, programmatic resources and data sets which include workspace data 155 of the user or user's account. As used herein, the term “workspace data” refers to data describing a design interface that can be loaded by the IGDS 100, the term “design interface under edit” (DIUE) refers to a design interface that is loaded in the IGDS 100, and the term “active workspace data” refers to workspace data describing a DIUE 125 that is loaded in the IGDS 100.

The program interface 102 may also retrieve programmatic resources that include an application framework for use with the canvas 122. The application framework can include data sets that define or configure a set of interactive graphic tools that integrate with the canvas 122. For example, the interactive graphic tools may include an input interface 118 to enable the user to provide input for creating and/or editing a design interface.

According to some examples, the input interface 118 can be implemented as a functional layer that is integrated with the canvas 122 to detect and interpret user input, such as the input interface 118. In one or more embodiments, the input interface 118 includes a user interface that can, for example, use a reference of the canvas 122 to identify a screen location of a user input (e.g., ‘click’). Additionally, the input interface 118 can interpret an input action of the user based on the location of the detected input (e.g., whether the position of the input indicates selection of a tool, an object rendered on the canvas, or region of the canvas), the frequency of the detected input in a given time period (e.g., double-click), and/or the start and end position of an input or series of inputs (e.g., start and end position of a click and drag), as well as various other input types which the user can specify (e.g., right-click, screen-tap, etc.) through one or more input devices. In this manner, the input interface 118 can interpret, for example, a series of inputs as a design tool selection (e.g., shape selection based on location/s of input), as well as inputs to define properties (e.g., dimensions) of a selected shape.

In examples, the workspace data 155 includes one or more data sets that represent a corresponding design interface that is in progress (e.g., DIUE 125) and can be rendered by rendering engine 120. More specifically, the workspace data 155 can include one or more hierarchical structures 157 which collectively define the DIUE. In some examples, the hierarchical structures 157 define a collection of layers, where each layer corresponds to an object, group of objects, or specific type of object. Further, in some examples, the hierarchical structures 157 can represent various screens within a design interface, such as one or more pages (e.g., with one canvas per page) and/or sections that include one or multiple pages.

In some examples, the rendering engine 120 and/or other components utilize graphics processing unit (GPU) accelerated logic, such as provided through WebGL (Web Graphics Library) programs which execute Graphics Library Shader Language (GLSL) programs that execute on GPUs. In variations, the application 80 can be implemented as a dedicated web-based application that is optimized for providing functionality as described with various examples. Further, the application 80 can vary based on the type of user device, including the operating system used by the user device 10 and/or the form factor of the user device (e.g., desktop computer, tablet, mobile device, etc.).

The rendering engine 120 renders the DIUE 125 described by the workspace data 155 on the canvas 122. For example, when a given version of a design interface is selected as the DIUE 125, the rendering engine 120 renders the design interface as described by the corresponding version of workspace data 155. The DIUE 125 includes graphic elements and their respective properties as described by one or more hierarchical structure 157 in the workspace data 155. The user can edit the DIUE 125 using the input interface 118. As an addition or alternative, the rendering engine 120 can generate a blank page for the canvas 122, and the user can use the input interface 118 to generate the DIUE 125. As rendered, the DIUE 125 can include graphic elements such as a background and/or a set of objects (e.g., shapes, text, images, programmatic elements), as well as properties of the individual graphic elements. Each property of a graphic element can include a property type and a property value. For an object, the types of properties include shape, dimension (or size), layer, type, color, line thickness, font color, font family, font size, font style, and/or other visual characteristics. Depending on implementation details, the properties reflect attributes of two- or three-dimensional designs. In this way, property values of individual objects can define visual characteristics such as size, color, positioning, layering, and content for elements that are rendered as part of the DIUE 125. Hierarchical structures 157 within workspace data 155 for the design interface can include nodes and/or layers describing one or more objects belonging to the design interface.

Individual design elements may also be defined in accordance with a desired run-time behavior. For example, some objects can be defined to have run-time behaviors that are either static or dynamic. The properties of dynamic objects may change in response to predefined run-time events generated by the underlying application that is to incorporate the DIUE 125. Additionally, some objects may be associated with logic that defines the object as being a trigger for rendering or changing other objects, such as through implementation of a sequence or workflow. Still further, other objects may be associated with logic that provides the design elements to be conditional as to when they are rendered and/or their respective configuration or appearance when rendered. Still further, objects may also be defined to be interactive, where one or more properties of the object may change based on user input during the run-time of the application.

The input interface 118 can process at least some user inputs to determine input information indicating (i) an input action type (e.g., shape selection, object selection, sizing input, color selection), (ii) an object or objects that are affected by the input action (e.g., an object being resized), (iii) a desired property that is to be altered by the input action, and/or (iv) a desired value for the property being altered. The program interface 102 can receive the input information and implement changes indicated by the input information to update the workspace data 155. The rendering engine 120 can update the canvas 122 to reflect the changes to the affected objects in the DIUE 125. For example, when a given version of the design interface is selected as the DIUE 125, the program interface 102 updates the corresponding version of the workspace data 155, and the rendering engine 120 updates the canvas 122 to reflect changes to the design interface indicated by the input information.

### Collaborative Environment

In examples, the IGDS 100 can be implemented as part of a collaborative platform, where a graphic design can be viewed and edited by multiple users operating different computing devices at locations. As part of a collaborative platform, when a user updates the DIUE 125 and/or workspace data 155 on the computing device 10, the changes made by the user are implemented in real-time to instances of the DIUE 125 and/or workspace data 155 on the computing devices of other collaborating users. Likewise, when other collaborators make changes to the DIUE 125, the changes are reflected in real-time within the hierarchical structures 157. The rendering engine 120 can update the workspace data 155 and/or DIUE 125 in real-time to reflect changes to the graphic design by the collaborators.

In implementation, when the rendering engine 120 implements a change to the workspace data 155 and/or DIUE 125, corresponding change data 121 representing the change can be transmitted to the network computer system 150. The network computer system 150 can implement one or more synchronization processes (represented by a service component 152) to maintain a network-side representation of the workspace data 155. In response to receiving the change data 121 from the computing device 10, the network computer system 150 updates the network-side representation of the workspace data 155 and transmits the change data 121 to user devices of other collaborators. Likewise, if another collaborator makes a change to the instance of the workspace data 155 on their respective device, corresponding change data 121 can be communicated from the collaborator device to the network computer system 150. The service component 152 updates the network-side representation of the workspace data 155 and transmits corresponding change data 121 to the user device 10 to update the hierarchical structures 157 and the DIUE 125.

### Generative Filling of Design Content

In some embodiments, the IGDS 100 includes functionality to perform generative filling of design content, in which a portion of a design interface that includes a set of repeating design elements 162 is automatically populated with content outputted by a generative model and/or another type of machine learning model. As shown in FIG. 1, program interface 102 and/or input interface 118 include functionality to manage the creation, collection, transmission, and/or update of fill data 130 that is used to populate one or more of the repeating design elements 162 with generated content 138 that is similar to example content 136 from one or more of the repeating design elements 162.

More specifically, input interface 118 may receive user input associated with a selection 132 of repeating design elements 162 within a given design interface (e.g., DIUE 125). For example, input interface 118 may receive keyboard, cursor, gesture, voice, and/or other types of user input specifying the selection 132 of the repeating design elements 162, the selection 132 of a portion of the design interface that includes the repeating design elements 162, and/or another type of selection 132 that includes or otherwise specifies the repeating design elements 162. Input interface 118 may also, or instead, receive a user selection 132 of a button and/or another user-interface element that represents a “trigger” for filling some or all of the repeating design elements 162 with the generated content 138. Input interface 118 may also, or instead, determine that the selection 132 corresponds to the duplication of one or more design elements in the design interface by the user.

In one or more embodiments, the repeating design elements 162 are included in one or more instances of a reusable main component that defines properties of one or more design elements. Each instance may be a copy of the main component and is linked to the main component. Each instance may also receive updates made to the main component. The repeating design elements 162 may also, or instead, be found in other types of design elements and/or entities within a given design interface.

The selection 132 and/or one or more portions of hierarchical structures 157 associated with the selection 132 are transmitted to the service component 152 and relayed by the service component 152 to a detector 154 on network computer system 150. An instance of the detector 154 may also, or instead, execute within and/or in conjunction with the program interface 102 on the computing device 10 to reduce latency and/or resource overhead associated with transmitting the selection 132 and/or corresponding portion(s) of hierarchical structures 157 from the computing device 10 to the network computer system 150. The detector 154 analyzes the portion(s) of hierarchical structures 157 to determine if the selection 132 includes and/or is otherwise associated with a set of repeating design elements 162.

In one or more embodiments, the detector 154 performs a breadth-first search of the hierarchical structures 157 to identify repeating design elements 162 associated with the selection 132. This breadth-first search may begin at a certain level within the portion(s) of the hierarchical structures 157 associated with the selection 132 (e.g., the highest level of nodes associated with the selection 132) and proceed to successively lower levels within the portion(s) of the hierarchical structures 157. At a given level, the detector 154 may compare names, visual attributes (e.g., size, shape, color, layout, position, font, style, dimension, line thickness, etc.), and/or other values associated with nodes in the level. If the values match and/or are within a threshold similarity to one another (e.g., based on semantic similarity, edit distance, scores outputted by one or more machine learning models, embeddings of the values, etc.), the detector 154 may determine that the corresponding nodes and/or layers match one another. If the values do not match and/or are not within a threshold similarity to one another, the detector 154 may determine that the corresponding nodes and/or layers do not match one another.

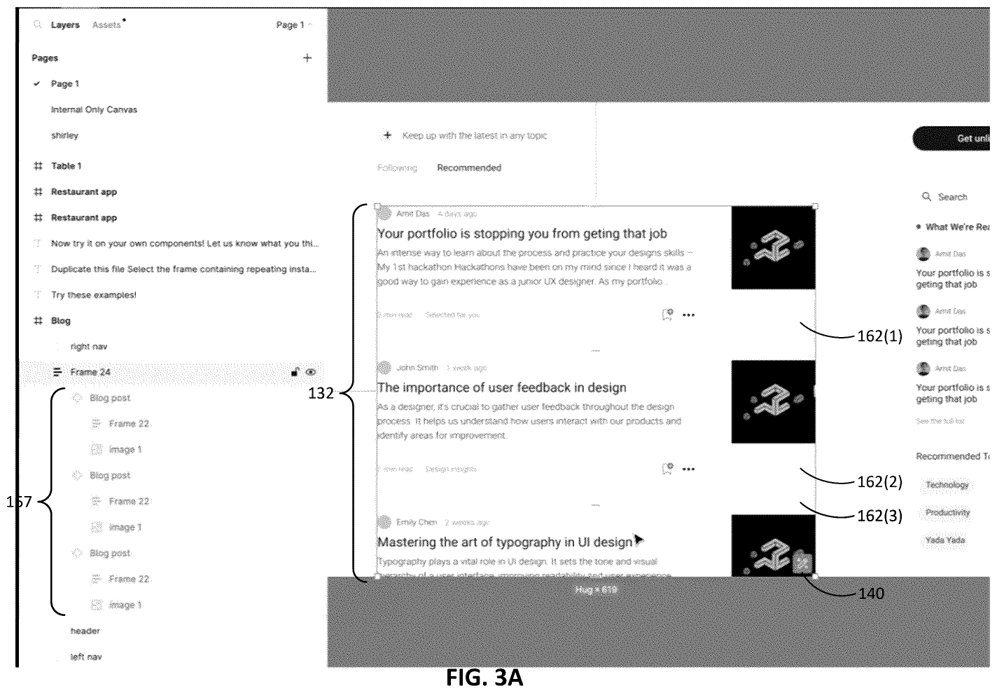

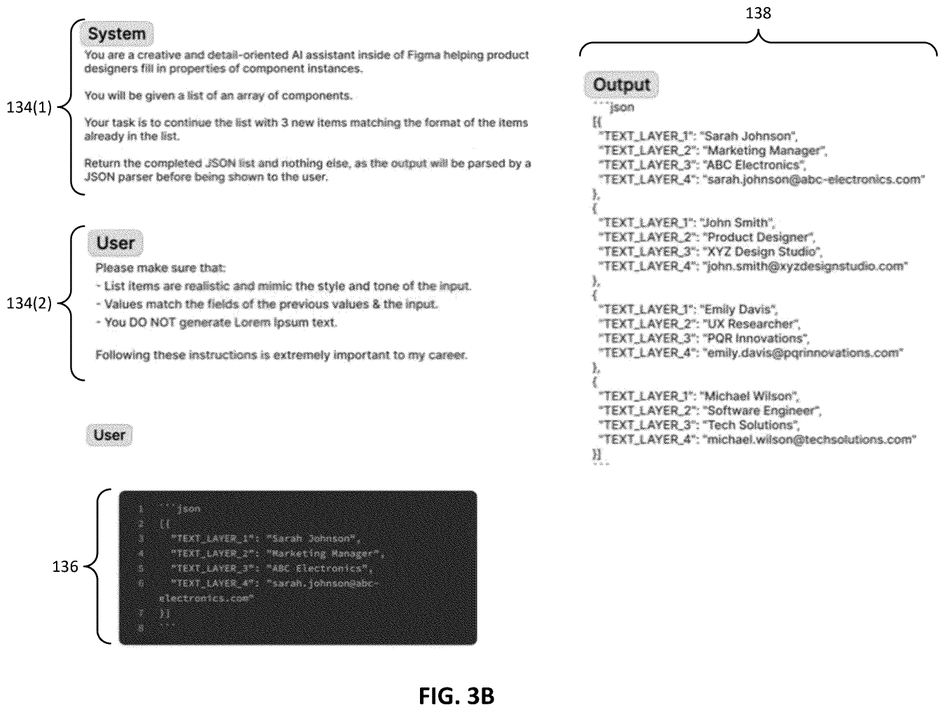

Once the detector 154 identifies a set of nodes that match one another at a certain level within portion(s) of the hierarchical structures 157 associated with the selection 132, the detector 154 repeats the process with additional levels of nodes that are direct and/or indirect descendants of the set of nodes. For example, the detector 154 may retrieve nodes that are children of the highest level of nodes that match one another within the portion(s) of the hierarchical structures 157. The detector 154 may compare individual and/or aggregated values associated with the retrieved nodes to determine the level of similarity across the nodes. When the level of similarity indicates that the retrieved nodes match one another, the detector 154 may repeat the comparison with additional nodes that are children of the most recently compared nodes until the lowest level of nodes is reached, a certain number of levels of nodes has been compared, and/or another condition is met. Determining repeating design elements 162 via analysis of layers of hierarchical structures 157 is described in further detail below with respect to FIG. 3A.

After the detector 154 has determined that the selection 132 includes and/or is associated with a set of repeating design elements 162, the detector 154 causes a trigger 140 to be outputted via the input interface 118 and/or rendering engine 120. For example, the detector 154 may generate an event, command, and/or other output that causes a user-interface element corresponding to trigger 140 to be displayed in association with (e.g., next to, within, etc.) the selection 132 on the canvas 122. The user-interface element may include a button, an ability to “expand” or “continue” the repeating design elements 162 (e.g., via a “drag” command, gesture, or symbol), a text-based “suggestion” to populate and/or expand the repeating design elements 162, and/or another indication that repeating design elements 162 have been detected in association with the selection 132. The user may select and/or interact with the trigger 140 to initiate the process of filling some or all of the repeating design elements 162 with generated content 138 that is similar to example content 136 from one or more of the repeating design elements 162.

More specifically, after trigger 140 is selected and/or otherwise activated, the program interface 102 generates and/or receives one or more instructions 134 associated with the generated content 138. For example, the instructions 134 may include a system instruction that is provided by IGDS 100 and specifies a role occupied by a large language model and/or a task to be performed by the large language model in producing the generated content 138. The instructions 134 may also, or instead, include a user instruction that is provided by a user and specifies additional customizations and/or instructions related to the generated content 138 (e.g., instructions related to the style, substance, appearance, and/or other attributes of the generated content 138). This user instruction may be received via one or more user-interface elements included in and/or associated with trigger 140.

The program interface 102 also determines example content 136 associated with the repeating design elements 162. For example, the program interface 102 may extract example content 136 in the form of text, visual attributes of layers within the repeating design elements 162, images, audio, video, animations, and/or other types of content that can be added to the repeating design elements 162 and/or used to alter the appearance of the repeating design elements 162. This example content 136 may be extracted from one or more repeating design elements 162 (e.g., the first repeating design element, the first N repeating design elements 162, a user selection 132 of one or more repeating design elements 162, etc.), provided by a user (e.g., as one or more files, freeform text, uploads, hyperlinks, etc.), extracted from one or more other design elements that are not included in the repeating design elements 162 (e.g., design elements from another portion of the design interface and/or a different design interface that serve as a “template” for generated content 138 within the repeating design elements 162), and/or obtained from another source.

The program interface 102 transmits the selection 132, instructions 134, and example content 136 to a generative engine 156 executing on the network computer system 150 (or another computer system to which the computing device 10 is connected via one or more networks). The generative engine 156 includes and/or has access to (e.g., via an application programming interface (API) and/or another type of interface) a large language model (LLM), generative model, and/or another machine learning model that is capable of generating content that is similar to the example content 136. The generative engine 156 provides the selection 132, instructions 134, and example content 136 as input into the machine learning model (e.g., in the form of one or more LLM prompts) and receives the generated content 138 as corresponding output of the machine learning model. Instructions 134, example content 136, and generated content 138 associate with repeating design elements 162 are described in further detail below with respect to FIG. 3B.

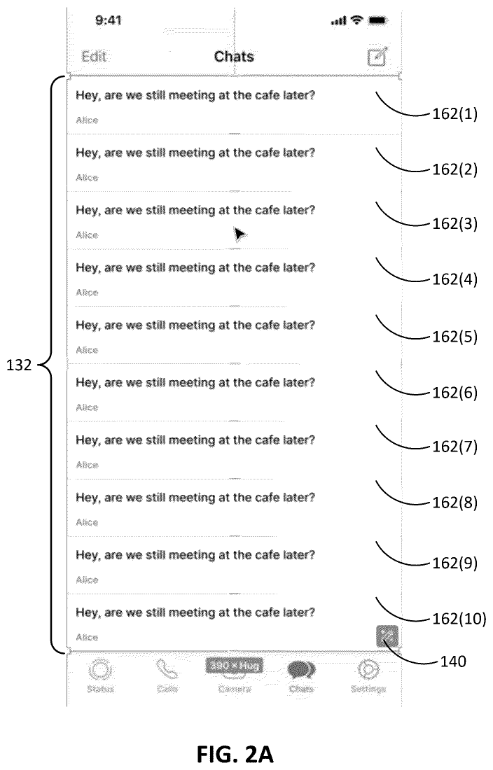

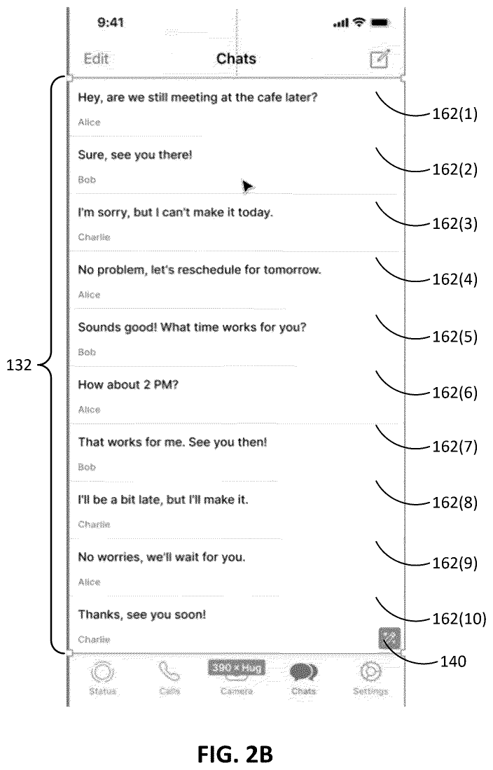

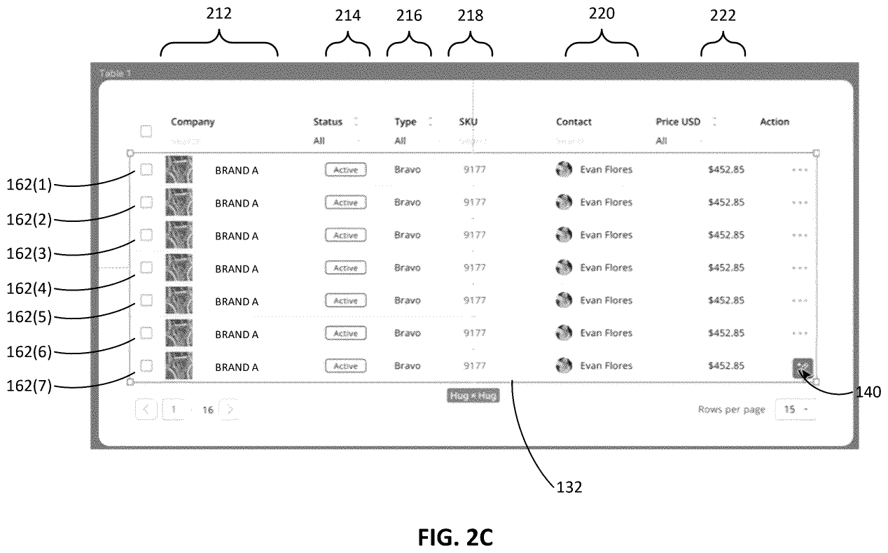

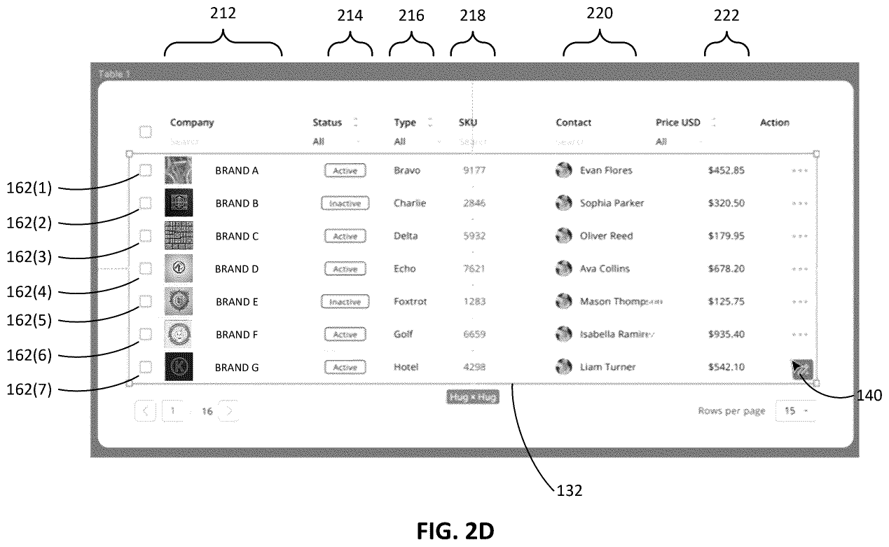

The generative engine 156 transmits the generated content 138 to the IGDS 100 executing on computing device 10 (e.g., in a response to a request from the computing device 10 that includes the selection 132, instructions 134, and/or example content 136). Alternatively, the generative engine 156 may execute on computing device 10 (e.g., by providing a local instance of the machine learning model) and transmit the generated content 138 directly to the program interface 102 and/or another component of the IGDS 100. The IGDS 100 incorporates the generated content 138 into some or all of the repeating design elements 162. For example, the IGDS 100 may incorporate text content, images, visual attributes, and/or other values in the generated content 138 into hierarchical structure 157 representing and/or defining the repeating design elements 162. The IGDS 100 may also use the rendering engine 120 to render the repeating design elements 162 with the incorporated generated content 138. The incorporation of the generated content 138 into the repeating design elements 162 thus allows the portion of the design interface that includes the repeating design elements 162 to be created more quickly and efficiently than conventional design tools that require manual editing and/or modification of individual repeating design elements by designers. Incorporation of generated content 138 into repeating design elements 162 is described in further detail below with respect to FIGS. 2A-2D.

### Example Design Interfaces and Fill Data

FIG. 2A illustrates an example rendering of a design interface that includes a set of repeating design elements 162(1)-162(10) in accordance with one or more embodiments. For example, the design interface may be rendered on a canvas by an IGDS (e.g., IGDS 100 of FIG. 1).

As shown in FIG. 2A, the repeating design elements 162(1)-162(10) include messages that are arranged in a list within the design interface. Each design element 162(1)-162(10) includes the same first line of text content of “Hey, are we still meeting at the cafe later?” and the same second line of text content of “Alice.”

The example design interface of FIG. 2A also includes a selection 132 of the repeating design elements 162(1)-162(10). For example, a user may make the selection 132 by drawing a rectangle around the repeating design elements 162(1)-162(10), performing a multiple selection of individual repeating design elements 162(1)-162(10), and/or otherwise providing input specifying the selection 132.

After the selection 132 is made, the detector 154 analyzes nodes and/or layers of one or more hierarchical structures 157 associated with the selection 132 to determine that the selection 132 includes repeating design elements 162(1)-162(10). For example, the detector 154 may determine that multiple repeating design elements 162(1)-162(10) with the same and/or similar structure are included in the selection 132 by matching names, attributes, embeddings, and/or other representations of nodes and/or layers in the corresponding hierarchical structures 157 to one another.

After the detector 154 determines that the selection 132 includes repeating design elements 162(1)-162(10), the detector 154 generates output that causes a corresponding trigger 140 to be displayed at the lower right corner of the selection 132. In the example of FIG. 2A, the trigger 140 includes a button that can be selected to cause some or all of the repeating design elements 162(1)-162(10) to be updated with generated content that is similar to the content from one or more of the repeating design elements 162(1)-162(10).

FIG. 2B illustrates an example rendering of a design interface that includes a set of repeating design elements in accordance with one or more embodiments. More specifically, FIG. 2B illustrates the rendering of the design interface of FIG. 2A after the trigger 140 has been selected. For example, the design interface of FIG. 2B may be rendered after a machine learning model has been used to generate text content in repeating design elements 162(2)-162(10) that is similar to the text content of “Hey, are we still meeting at the cafe later?” and “Alice” that was originally included in all of the repeating design elements 162(1)-162(10).

As shown in FIG. 2B, the first repeating design element 162(1) continues include the original text content of “Hey, are we still meeting at the cafe later?” and the “Alice.” On the other hand, each of the subsequent repeating design elements 162(2)-162(10) includes a first line of text content that corresponds to a different message and a second line of text content that corresponds to a name of a user from which the message was received.

While the example design interface of FIG. 2B includes a first repeating design element 162(1) that is populated with the original text content of “Hey, are we still meeting at the cafe later?” and “Alice,” it will be appreciated that the first repeating design element 162(1) may also be replaced with generated content that is similar to the original text content (e.g., based on additional prompting and/or instructions from a user creating and/or modifying the design interface). Similarly, the trigger 140 may be reselected to update the design interface with a different set of text content that is similar to the text content in one or more repeating design elements 162(1)-162(10). For example, a user may customize the generation of text content in one or more repeating design elements 162(1)-162(10) by hovering over, selecting, and/or otherwise interacting with the trigger 140 and providing a custom user instruction via a text field and/or another user-interface element that is shown in response to the interaction with the trigger 140. The custom user instruction may specify one or more repeating design elements 162(1)-162(10) as sources of example content to be used as a basis for the generated content, freeform text that should be used as example content, one or more repeating design elements 162(1)-162(10) to be updated with newly generated content, one or more repeating design elements 162(1)-162(10) that should not be updated with newly generated content, preferences related to the generated content (e.g., names, message lengths, message content, visual attributes, styles, colors, etc.), and/or other parameters related to the generated content.

FIG. 2C illustrates an example rendering of a design interface that includes a set of repeating design elements 162(1)-162(7) in accordance with one or more embodiments. As with the example design interface of FIGS. 2A-2B, the design interface of FIG. 2C may be rendered on a canvas by an IGDS (e.g., IGDS 100 of FIG. 1).

As shown in FIG. 2C, the repeating design elements 162(1)-162(7) include rows of cells within a table. The cells are organized into multiple columns 212, 214, 216, 218, 220, and 222 that represent different types of data in the cells. All cells in the first column 212 correspond to a “Company” data type and include the same value of “Louis Vuitton,” all cells in the second column 214 correspond to a “Status” data type and include the same value of “Active,” all cells in the third column 216 correspond to a “Type” data type and include the same value of “Bravo,” all cells in the fourth column 218 correspond to an “SKU” data type and include the same value of “9177,” all cells in the fifth column 220 correspond to a “Contact” data type and include the same value of “Evan Flores,” and all cells in the sixth column 222 correspond to a “Price USD” data type and include the same value of “$452.85.”

The example design interface of FIG. 2C also includes a selection 132 of the repeating design elements 162(1)-162(7). For example, a user may make the selection 132 by drawing a rectangle around the repeating design elements 162(1)-162(7), performing a multiple selection of individual repeating design elements 162(1)-162(7), and/or otherwise providing input specifying the selection 132.

After the selection 132 is made, the detector 154 analyzes nodes and/or layers of one or more hierarchical structures 157 associated with the selection 132 to determine that the selection 132 includes the repeating design elements 162(1)-162(7). For example, the detector 154 may determine that multiple repeating design elements 162(1)-162(7) with the same and/or similar structure are included in the selection 132 by matching names, attributes, embeddings, and/or other representations of nodes and/or layers representing the rows, columns 212, 214, 216, 218, 220, and 222, and/or cells within the selection 132 to one another.

After the detector 154 determines that the selection 132 includes repeating design elements 162(1)-162(7), the detector 154 generates output that causes a corresponding trigger 140 to be displayed at the lower right corner of the selection 132. In the example of FIG. 2A, the trigger 140 includes a button that can be selected to cause some or all of the repeating design elements 162(1)-162(7) to be updated with generated content that is similar to the content from one or more of the repeating design elements 162(1)-162(7).

FIG. 2D illustrates an example rendering of a design interface that includes a set of repeating design elements in accordance with one or more embodiments. More specifically, FIG. 2D illustrates the rendering of the design interface of FIG. 2C after the trigger 140 has been selected. For example, the design interface of FIG. 2D may be rendered after a machine learning model has been used to generate text content in the last six repeating design elements 162(2)-162(7) that is similar to the text content of “Louis Vuitton,” “Active,” “Bravo,” “9177,” “Evan Flores,” and “$452.85” that was originally included in all of the repeating design elements 162(1)-162(7).

As shown in FIG. 2D, the first repeating design element 162(1) continues to be populated with the original text content of “Louis Vuitton,” “Active,” “Bravo,” “9177,” “Evan Flores,” and “$452.85.” On the other hand, each of the subsequent repeating design elements 162(2)-162(7) includes a different value for the “Company,” “Status,” “Type,” “SKU,” “Contact,” and “Price USD” fields corresponding to columns 212, 214, 216, 218, 220, and 222.

While the example design interface of FIG. 2B includes a first repeating design element 162(1) that is populated with the original text content of Louis Vuitton,” “Active,” “Bravo,” “9177,” “Evan Flores,” and “$452.85,” it will be appreciated that the first repeating design element 162(1) may also be replaced with generated content that is similar to the original text content (e.g., based on additional prompting and/or instructions from a user creating and/or modifying the design interface). Similarly, the trigger 140 may be reselected to update the design interface with a different set of text content that is similar to the text content in one or more repeating design elements 162(1)-162(7). For example, a user may customize the generation of text content in one or more repeating design elements 162(1)-162(87) by hovering over, selecting, and/or otherwise interacting with the trigger 140 and providing a custom user instruction via a text field and/or another user-interface element that is shown in response to the interaction with the trigger 140. The custom user instruction may specify one or more repeating design elements 162(1)-162(7) as sources of example content on which the generated content is to be based, freeform text to be used as the example content, one or more repeating design elements 162(1)-162(7) to be updated with newly generated content, one or more repeating design elements 162(1)-162(7) that should not be updated with newly generated content, preferences related to the generated content (e.g., formatting, styles, and/or restrictions associated with the company names, statuses, types, names, prices, etc.), and/or other parameters related to the generated content.

FIG. 3A illustrates a rendering of an example design interface and a set of hierarchical structures 157 representing a set of repeating design elements 162(1)-162(3) within the design interface in accordance with one or more embodiments. As shown in FIG. 3A, the design interface may be rendered on a canvas by an IGDS (e.g., IGDS 100 of FIG. 1) and includes three repeating design elements 162(1)-162(34) corresponding to blog post summaries.

The example design interface of FIG. 3A also includes a selection 132 of the repeating design elements 162(1)-162(3). For example, a user may make the selection 132 by drawing a rectangle around the repeating design elements 162(1)-162(3), performing a multiple selection of individual repeating design elements 162(1)-162(3), and/or otherwise providing input specifying the selection 132.

In response to the selection 132, a left sidebar is updated to highlight a set of hierarchical structures 157 associated with the selection. The highlighted hierarchical structures 157 include three sets of layers corresponding to the three repeating design elements 162(1)-162(3). Each set of layers includes a topmost layer named “Blog post,” a second layer named “Frame 22” that is a child of the topmost layer, and a layer named “image 1” that is a child of the second layer.

The names, relationships, and/or other attributes associated with these layers may be analyzed by the detector 154 to determine that the selection 132 includes repeating design elements 162(1)-162(3). For example, the detector 154 may determine that multiple repeating design elements 162(1)-162(3) with the same and/or similar structure are included in the selection 132 by matching names, attributes, embeddings, and/or other representations of nodes and/or layers representing design elements within the selection 132 to one another, starting with the topmost layer and progressing to lower-level layers. In response to the detector 154 determining that the selection 132 includes the repeating design elements 162(1)-162(3), the trigger 140 is displayed in the lower right corner of the selection 132. A user may select and/or otherwise interact with the trigger 140 and/or additional user-interface elements associated with the trigger to populate some or all of the repeating design elements 162(1)-162(3) with generated content that is similar to the content in one or more of the repeating design elements 162(1)-162(3), as discussed above. The user may also, or instead, “drag” the selection downward (e.g., using a bar, handle, and/or other type of user-interface element) to trigger the addition of more repeating user elements and corresponding generated content to the bottom of the list.

FIG. 3B illustrates a set of fill data 130 associated with a set of repeating design elements 162 in accordance with one or more embodiments. As shown in FIG. 3B, the fill data 130 includes a system instruction 134(1), a user instruction 134(2), a set of example content 136, and a set of generated content 138.

In some embodiments, the system instruction 134(1) is generated and/or provided by the IGDS 100. In the example of FIG. 3B, the system instruction 134(1) describes the role of an LLM (or another type of machine learning model), the input provided to the LLM, a task to be performed by the LLM, and output to be generated by the LLM. The system instruction 134(1) may be updated and/or customized to various use cases associated with generating content for use in filling repeating design elements. For example, the system instruction 134(1) may include a different role description, a different number of new items to generate, a different format associated with the output, and/or other details or instructions that can be used to guide the operation of the LLM in the task of filling design content.

The user instruction 134(2) may be generated and/or provided by a user. For example, the user instruction 134(2) may be specified by the user via a text field and/or another type of user-interface element during interaction with a trigger (e.g., trigger 140) for generating content associated with the repeating design elements. In the example of FIG. 3B, the user instruction 134(2) includes customizations related to the style and tone of the generated content 138, the formatting of the generated content 138, and/or types of text to not generate.

The example content 136 may be extracted from one or more repeating design elements 162. For example, the example content 136 may include data from a design element that is formatted using JavaScript Object Notation (JSON). This design element may include the first repeating design element in a selection of multiple repeating design elements 162, a user-specified design element, and/or a design element that is selected via other criteria. As shown in FIG. 3B, the example content 136 includes four attribute-value pairs, where each attribute corresponds to a different layer in the design element and each value corresponds to text content to be incorporated into the layer. The first attribute-value pair specifies a name, the second attribute-value pair specifies a role, the third attribute-value pair specifies a company, and the fourth attribute-value pair specifies an email address.

The generated content 138 includes four sets of attribute-value pairs that adhere to the JSON format of the attribute-value pair in the example content 136. The first attribute-value pair is identical to that of the example content 136, while the second, third, and fourth attribute-value pairs are different from that of the example content 136. More specifically, each of the second, third, and fourth attribute-value pairs includes a different name, role, company, and email address from that of the first attribute-value pair. The second, third, and fourth attribute-value pairs may be generated by the LLM after the system instruction 134(1), user instruction 134(2), and example content 136 are inputted into the LLM in the form of one or more prompts.

### Methodology

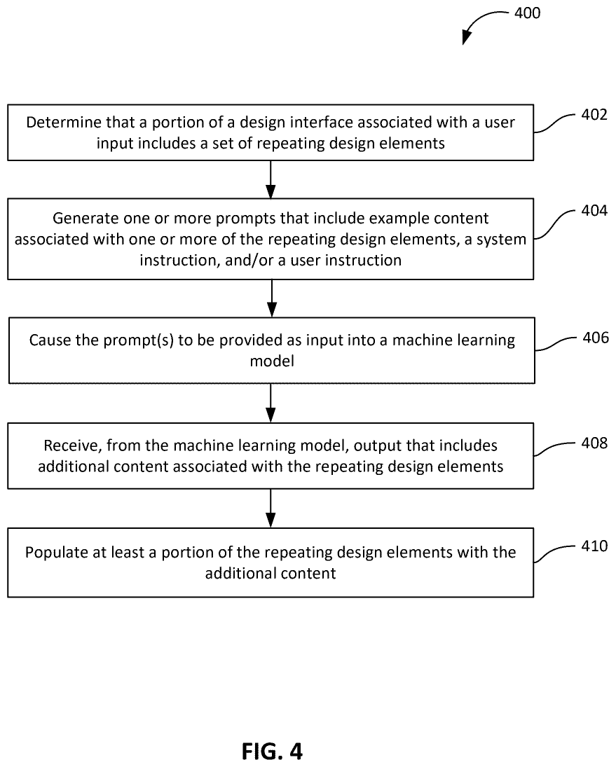

FIG. 4 illustrates a process 400 for performing generative filling of design content in accordance with one or more embodiments. Process 400 may be performed by one or more computing devices and/or processes thereof. For example, one or more blocks of process 400 may be performed by a user computing device (e.g., user computing device 10) and/or a network computer system (e.g., network computer system 150, 50).

At block 402, a computing device, which may include (but is not limited to) the user computing device and/or network computer system, determines that a portion of a design interface associated with a user input includes a set of repeating design elements. For example, the computing device may receive user input that specifies and/or includes a selection of the portion of the design interface. The computing device may also, or instead, receive user input that indicates a duplication of one or more design elements a certain number of times. The computing device may also, or instead, receive user input that corresponds to a trigger to perform generative filling of content in the repeating design elements. The computing device may also perform a breadth-first search of one or more hierarchical structures defining the selected portion of the design interface to determine that the selected portion includes repeating design elements. During the breadth-first search, the computing device may compare names, properties, and/or other values associated with nodes at a given layer of the hierarchical structure(s). If the values match and/or are within a threshold similarity to one another, the computing device may determine that the corresponding nodes match and repeat the process with the next lowest layer of nodes in the hierarchical structure(s). The computing device may repeat the process until the lowest layer of nodes in the hierarchical structure(s) is reached, matches are found in nodes from a certain number of consecutive layers within the hierarchical structure(s), and/or another condition is met. The computing device may thus determine that the selected portion of the design interface includes repeating design elements if some or all layers of nodes in the corresponding hierarchical structure(s) match.

At block 404, the computing device generates one or more prompts that include example content associated with one or more of the repeating design elements, a system instruction, and/or a user instruction. For example, the computing device may extract the example content from the first repeating design element and/or one or more repeating design elements specified by the user. The computing device may also, or instead, receive the example content from the user (e.g., in the form of text input, one or more files, etc.). The computing device may also, or instead, generate and/or retrieve a system instruction that describes the role of a machine learning model (e.g., LLM, generative model, etc.), one or more tasks to be performed by the machine learning model, the behavior of the machine learning model, and/or other instructions related to generative filling of design content by the machine learning model. The computing device may also, or instead, receive a user instruction from the user via one or more user-interface elements and/or types of user input. The user instruction may include user-specified preferences and/or customizations related to the content generated by the LLM.

At block 406, the computing device causes the prompt(s) to be provided as input into the machine learning model. For example, the computing device may use an API and/or another type of interface to transmit the prompt(s) to the machine learning model.

At block 408, the computing device receives, from the machine learning model, output that includes additional content associated with the repeating design elements. Continuing with the above example, the computing device may receive, via the API and/or interface, text content, images, visual attributes, audio, video, and/or other types of output generated by the machine learning model in response to the prompt(s).

At block 410, the computing device populates at least a portion of the repeating design elements with the content. For example, the computing device may update one or more JSON objects and/or other representations of the repeating design elements and/or corresponding hierarchical structure(s) to include the content. The computing device may also render the repeating design elements to with the incorporated content to allow the user to see the result of the generative filling process.

### Network Computer System

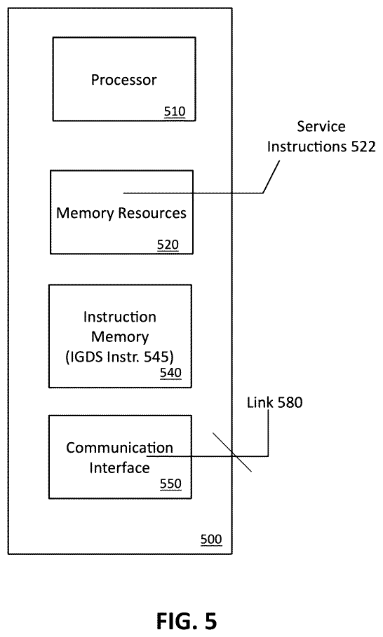

FIG. 5 illustrates a computer system on which one or more embodiments can be implemented. A computer system 500 can be implemented on, for example, a server or combination of servers. For example, the computer system 500 may be implemented as the network computer system 150 of FIG. 1.

In one implementation, the computer system 500 includes processing resources 510, memory resources 520 (e.g., read-only memory (ROM) or random-access memory (RAM)), one or more instruction memory resources 540, and a communication interface 550. The computer system 500 includes at least one processor 510 for processing information stored with the memory resources 520, such as provided by a random-access memory (RAM) or other dynamic storage device, for storing information and instructions which are executable by the processor 510. The memory resources 520 may also be used to store temporary variables or other intermediate information during execution of instructions to be executed by the processor 510.

The communication interface 550 enables the computer system 500 to communicate with one or more user computing devices, over one or more networks (e.g., cellular network) through use of the network link 580 (wireless or a wire). Using the network link 580, the computer system 500 can communicate with one or more computing devices, specialized devices and modules, and/or one or more servers.

In examples, the processor 510 may execute service instructions 522, stored with the memory resources 520, in order to enable the network computer system to implement the service component 152, detector 154, and generative engine 156 and operate as the network computer system 150 in examples such as described with respect to FIG. 1.

The computer system 500 may also include additional memory resources (“instruction memory 540”) for storing executable instruction sets (“IGDS instructions 545”) which are embedded with webpages and other web resources, to enable user computing devices to implement functionality such as described with the IGDS 100.

As such, examples described herein are related to the use of the computer system 500 for implementing the techniques described herein. According to an aspect, techniques are performed by the computer system 500 in response to the processor 510 executing one or more sequences of one or more instructions contained in the memory 520. Such instructions may be read into the memory 520 from another machine-readable medium. Execution of the sequences of instructions contained in the memory 520 causes the processor 510 to perform the process steps described herein. In alternative implementations, hard-wired circuitry may be used in place of or in combination with software instructions to implement examples described herein. Thus, the examples described are not limited to any specific combination of hardware circuitry and software.

### User Computing Device

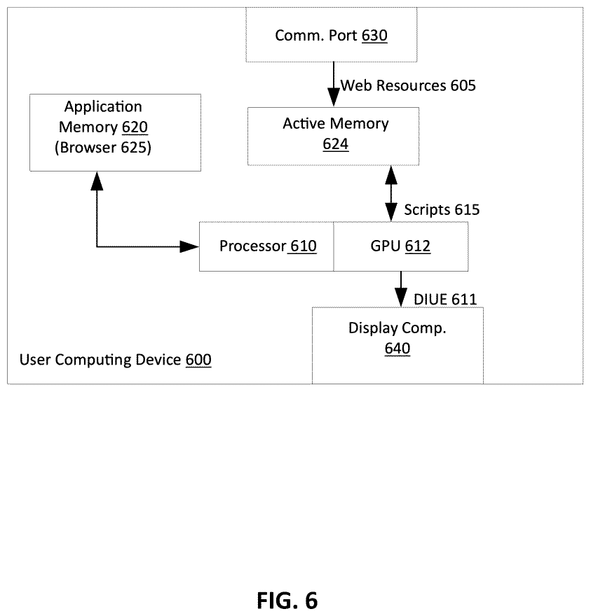

FIG. 6 illustrates a user computing device for use with one or more examples, as described. In examples, a user computing device 600 can correspond to, for example, a workstation, a desktop computer, a laptop, and/or another computer system having graphics processing capabilities that are suitable for enabling renderings of design interfaces and graphic design work. In variations, the user computing device 600 can correspond to a mobile computing device, such as a smartphone, tablet computer, laptop computer, VR or AR headset device, and the like.

In examples, the computing device 600 includes a central or main processor 610, a graphics processing unit 612, memory resources 620, and one or more communication ports 630. The computing device 600 can use the main processor 610 and the memory resources 620 to store and launch a browser 625 or other web-based application. A user can operate the browser 625 to access a network site of the network service, using the communication port 630, where one or more web pages or other resources 605 for the network service (see FIG. 1) can be downloaded. The web resources 605 can be stored in the active memory 624 (cache).

As described by various examples, the processor 610 can detect and execute scripts and other logic which are embedded in the web resource in order to implement the IGDS 100 (see FIG. 1). In some of the examples, some of the scripts 615 which are embedded with the web resources 605 can include GPU accelerated logic that is executed directly by the GPU 612. The main processor 610 and the GPU can combine to render a design interface under edit (“DIUE 611”) on a display component 640. The rendered design interface can include web content from the browser 625, as well as design interface content and functional elements generated by scripts and other logic embedded with the web resource 605. By including scripts 615 that are directly executable on the GPU 612, the logic embedded with the web resource 605 can better execute the IGDS 100, as described with various examples.

CLAUSE 1. In one or more embodiments, a computer system comprises: one or more processors; and a memory to store a set of instructions, wherein the one or more processors execute instructions stored in the memory to perform operations comprising: determining a set of repeating design elements within a design interface; determining input into a machine learning model that includes (i) example content associated with the set of repeating design elements and (ii) one or more instructions associated with the example content; and populating at least a portion of the set of repeating design elements with additional content generated by the machine learning model in response to the input.

CLAUSE 2. The computer system of clause 1, wherein the operations further comprise: receiving a user input associated with the set of repeating design elements prior to determining that the portion of the design interface includes the set of repeating design elements.

CLAUSE 3. The computer system of clauses 1 or 2, wherein the user input comprises a selection that includes the set of repeating design elements.

CLAUSE 4. The computer system of any of clauses 1-3, wherein the user input comprises an expansion of the set of repeating design elements.

CLAUSE 5. The computer system of any of clauses 1-4, wherein the user input comprises an interaction with a user-interface element associated with generation of the additional content.

CLAUSE 6. The computer system of any of clauses 1-5, wherein determining the set of repeating design elements within the design interface comprises: determining a first match associated with a first plurality of layers in a set of hierarchical structures representing the set of repeating design elements; and determining one or more additional matches associated with one or more pluralities of layers in the set of repeating design elements, wherein the one or more pluralities of layers are descendants of the first plurality of layers within the set of hierarchical structures.

CLAUSE 7. The computer system of any of clauses 1-6, wherein the first match is determined based on a level of similarity among the first plurality of layers.

CLAUSE 8. The computer system of any of clauses 1-7, wherein the first match is determined based on one or more attributes associated with the first plurality of layers.

CLAUSE 9. The computer system of any of clauses 1-8, wherein determining the one or more instructions comprises: receiving a custom instruction associated with the additional content from a user.

CLAUSE 10. The computer system of any of clauses 1-9, wherein determining the example content comprises extracting the example content from one or more design elements in the set of repeating design elements.

CLAUSE 11. The computer system of any of clauses 1-10, wherein the set of repeating design elements comprises at least one of a list or a table.

CLAUSE 12. The computer system of any of clauses 1-11, wherein the machine learning model comprises a generative model.

CLAUSE 13. In one or more embodiments, a non-transitory computer-readable medium stores instructions, executable by one or more processors, to cause the one or more processors to perform operations comprising: determining a set of repeating design elements within a design interface; determining input into a machine learning model that includes (i) example content associated with the set of repeating design elements and (ii) one or more instructions associated with the example content; and populating at least a portion of the set of repeating design elements with additional content generated by the machine learning model in response to the input.

CLAUSE 14. The non-transitory computer-readable medium of clause 13, wherein the operations further comprise: receiving a user input associated with the set of repeating design elements prior to determining that the portion of the design interface includes the set of repeating design elements.

CLAUSE 15. The non-transitory computer-readable medium of clause 13 or 14, wherein the user input comprises at least one of a selection of the portion of the design interface, an expansion of the set of repeating design elements, or an interaction with a user-interface element associated with generation of the additional content.

CLAUSE 16. The non-transitory computer-readable medium of any of clauses 13-15, wherein determining the set of repeating design elements within the design interface comprises: determining a first match associated with a first plurality of layers in a set of hierarchical structures representing the set of repeating design elements; and in response to determining the first match, determining a second match associated with a second plurality of layers in the set of repeating design elements, wherein the second plurality of layers includes children of the first plurality of layers within the set of hierarchical structures.

CLAUSE 17. The non-transitory computer-readable medium of c any of clauses 13-16, wherein determining the one or more instructions comprises: determining a system instruction that specifies a role and a task associated with a large language model.

CLAUSE 18. The non-transitory computer-readable medium of any of clauses 13-17, wherein the additional content comprises at least one of text content, a layer name, or a visual attribute of a design element.

CLAUSE 19. In one or more embodiments, a computer-implemented method comprises: determining a set of repeating design elements within a design interface; determining input into a machine learning model that includes (i) example content associated with the set of repeating design elements and (ii) one or more instructions associated with the example content; and populating at least a portion of the set of repeating design elements with additional content generated by the machine learning model in response to the input.

CLAUSE 20. The computer-implemented method of clause 19, wherein the machine learning model comprises a large language model.

### CONCLUSION

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. A computer system comprising:
one or more processors; and
a memory to store a set of instructions, wherein the one or more processors execute instructions stored in the memory to perform operations comprising:
determining a set of repeating design elements within a design interface;
determining input into a machine learning model that includes (i) example content associated with the set of repeating design elements and (ii) one or more instructions associated with the example content; and
populating at least a portion of the set of repeating design elements with additional content generated by the machine learning model in response to the input.

2. The computer system of claim 1, wherein the operations further comprise:
receiving a user input associated with the set of repeating design elements prior to determining that the portion of the design interface includes the set of repeating design elements.

3. The computer system of claim 2, wherein the user input comprises a selection that includes the set of repeating design elements.

4. The computer system of claim 2, wherein the user input comprises an expansion of the set of repeating design elements.

5. The computer system of claim 2, wherein the user input comprises an interaction with a user-interface element associated with generation of the additional content.

6. The computer system of claim 1, wherein determining the set of repeating design elements within the design interface comprises:
determining a first match associated with a first plurality of layers in a set of hierarchical structures representing the set of repeating design elements; and
determining one or more additional matches associated with one or more pluralities of layers in the set of repeating design elements, wherein the one or more pluralities of layers are descendants of the first plurality of layers within the set of hierarchical structures.

7. The computer system of claim 6, wherein the first match is determined based on a level of similarity among the first plurality of layers.

8. The computer system of claim 6, wherein the first match is determined based on one or more attributes associated with the first plurality of layers.

9. The computer system of claim 1, wherein determining the one or more instructions comprises:
receiving a custom instruction associated with the additional content from a user.

10. The computer system of claim 1, wherein determining the example content comprises extracting the example content from one or more design elements in the set of repeating design elements.

11. The computer system of claim 1, wherein the set of repeating design elements comprises at least one of a list or a table.

12. The computer system of claim 1, wherein the machine learning model comprises a generative model.

13. A non-transitory computer-readable medium that stores instructions, executable by one or more processors, to cause the one or more processors to perform operations comprising:
determining a set of repeating design elements within a design interface;
determining input into a machine learning model that includes (i) example content associated with the set of repeating design elements and (ii) one or more instructions associated with the example content; and
populating at least a portion of the set of repeating design elements with additional content generated by the machine learning model in response to the input.

14. The non-transitory computer-readable medium of claim 13, wherein the operations further comprise:
receiving a user input associated with the set of repeating design elements prior to determining that the portion of the design interface includes the set of repeating design elements.

15. The non-transitory computer-readable medium of claim 14, wherein the user input comprises at least one of a selection of the portion of the design interface, an expansion of the set of repeating design elements, or an interaction with a user-interface element associated with generation of the additional content.

16. The non-transitory computer-readable medium of claim 13, wherein determining the set of repeating design elements within the design interface comprises:
determining a first match associated with a first plurality of layers in a set of hierarchical structures representing the set of repeating design elements; and
in response to determining the first match, determining a second match associated with a second plurality of layers in the set of repeating design elements, wherein the second plurality of layers includes children of the first plurality of layers within the set of hierarchical structures.

17. The non-transitory computer-readable medium of claim 13, wherein determining the one or more instructions comprises:
determining a system instruction that specifies a role and a task associated with a large language model.

18. The non-transitory computer-readable medium of claim 13, wherein the additional content comprises at least one of text content, a layer name, or a visual attribute of a design element.

19. A computer-implemented method comprising:
determining a set of repeating design elements within a design interface;
determining input into a machine learning model that includes (i) example content associated with the set of repeating design elements and (ii) one or more instructions associated with the example content; and
populating at least a portion of the set of repeating design elements with additional content generated by the machine learning model in response to the input.

20. The computer-implemented method of claim 19, wherein the machine learning model comprises a large language model.
